(19) United States
(12) Patent Application Publication
(10) Pub. No.: US 2026/0190972 A1
(43) Pub. Date: Jul. 2, 2026

(54) SEMICONDUCTOR STRUCTURE AND IMAGE SENSOR

(71) Applicant: CXMT Corporation, Hefei (CN)

(72) Inventors: Tao Ma, Hefei (CN); Zhiyuan Xu, Hefei (CN); Jialin You, Hefei (CN)

(73) Assignee: CXMT Corporation, Hefei (CN)

(21) Appl. No.: 19/412,111

(22) Filed: Dec. 8, 2025

Related U.S. Application Data
(63) Continuation of application No. PCT/CN2025/131566, filed on Oct. 31, 2025.

(30) Foreign Application Priority Data
Jan. 2, 2025 (CN) 202510007696.9

(51) Int. Cl. H10W 20/20; H10F 39/00

(52) U.S. Cl. CPC H10W 20/2134; H10F 39/809; H10F 39/811

(57) ABSTRACT

Embodiments of the present disclosure relate to the field of image sensors and provide a semiconductor structure and an image sensor. The semiconductor structure may include at least: a base substrate; an epitaxial layer located on the base substrate; a first opening penetrating through the epitaxial layer into the base substrate; a first structure located in the first opening; and a second structure located below the first structure, the second structure being electrically connected to the first structure.

### CROSS-REFERENCE TO RELATED APPLICATIONS

This application is a continuation of International Patent Application No. PCT/CN2025/131566, filed on Oct. 31, 2025, which claims the benefit of Chinese Patent Application No. 202510007696.9, titled "SEMICONDUCTOR STRUCTURE AND IMAGE SENSOR", filed with the China National Intellectual Property Administration (CNIPA) on Jan. 2, 2025, the disclosures of which are incorporated herein by reference in their entireties.

### TECHNICAL FIELD

Embodiments of the present disclosure relate to the field of image sensors, and in particular, to a semiconductor structure and an image sensor.

### BACKGROUND

A CMOS image sensor, as a core component of modern image capture technology, integrates a low-power logic circuit with a high-quality pixel process to convert an external optical signal into a digital electrical signal. However, driven by the demands for high resolution and miniaturization, how to maintain the connection performance and stability between structures has become an urgent technical problem to be resolved.

### SUMMARY

Embodiments of the present disclosure provide a semiconductor structure and an image sensor, which are at least beneficial for improving the connection performance and structural stability of the CMOS image sensor.

According to some embodiments of the present disclosure, an aspect of the embodiments of the present disclosure provides a semiconductor structure. The semiconductor structure includes:

a base substrate;

an epitaxial layer located on the base substrate;

a first opening penetrating through the epitaxial layer into the base substrate;

a first structure located in the first opening; and

a second structure located below the first structure, the second structure being electrically connected to the first structure.

Another aspect of the embodiments of the present disclosure provides an image sensor. The image sensor includes:

a first semiconductor and a second semiconductor, where the first semiconductor is located on the second semiconductor, and the first semiconductor is composed of the semiconductor structure according to any one of claims 1 to 13;

the first semiconductor includes a base substrate and an epitaxial layer located on the base substrate; and

the second semiconductor includes a substrate and a structural layer located on the substrate, and a bonding layer is provided between a top surface of the structural layer and a bottom surface of the base substrate.

### BRIEF DESCRIPTION OF DRAWINGS

One or more embodiments are exemplarily illustrated with reference to figures in the corresponding drawings, and these exemplary illustrations are not to be construed as limiting the embodiments. Unless expressly stated otherwise, the figures in the drawings do not constitute a limitation of scale. To more clearly illustrate the technical solutions in the embodiments of the present disclosure or conventional technology, a brief introduction to the drawings required to be used in the embodiments is given hereinafter. It is evident that the drawings described hereinafter are merely some embodiments of the present disclosure. For those of ordinary skill in the art, other drawings may be further obtained based on these drawings without creative effort.

FIG. 1 is a schematic plan view of an image sensor device;

FIGS. 2 and 3 are schematic diagrams of a scanning electron microscope of an image sensor according to an embodiment;

FIG. 4 is a schematic diagram of a semiconductor structure according to the present disclosure;

FIG. 5 is a schematic diagram of another semiconductor structure according to the present disclosure;

FIGS. 6 to 8 are schematic top views of a first structure and a second structure according to the present disclosure;

FIG. 9 is a schematic diagram of an image sensor according to the present disclosure;

FIG. 10 is a schematic diagram of another image sensor according to the present disclosure;

FIG. 11 is a schematic diagram of an image sensor including a through structure according to the present disclosure; and

FIG. 12 is a schematic diagram of another image sensor including a through structure according to the present disclosure.

### DESCRIPTION OF EMBODIMENTS

As can be seen from the background, a CMOS image sensor, as a core component of modern image capture technology, integrates a low-power logic circuit with a high-quality pixel process to convert an external optical signal into a digital electrical signal. However, driven by the demands for high resolution and miniaturization, how to maintain the connection performance and maintain the structural stability between structures has become an urgent technical problem to be resolved.

Embodiments of the present disclosure provide a semiconductor structure and an image sensor. By providing a first structure and a second structure, where the second structure is located below the first structure and the second structure is electrically connected to the first structure, a region that is originally prone to cracking and deformation is filled by the second structure. This prevents the generation of cracks and deformation, thereby improving the structural stability and connection performance of the image sensor.

The embodiments of the present disclosure will be described in detail below with reference to the drawings. However, those of ordinary skill in the art can understand that, in the embodiments of the present disclosure, numerous technical details are set forth to enable readers to better understand the present disclosure. However, the technical solutions claimed by the present disclosure can also be implemented even without these technical details and the various changes and modifications based on the following embodiments. The present disclosure is more specifically described in the following paragraphs with reference to the drawings by way of example. The advantages and features of the present disclosure will become apparent from the following description and claims. It should be noted that the drawings are all in a very simplified form and not to a precise scale, and are provided only for the purpose of facilitating a convenient and clear description of the embodiments of the present disclosure.

It will be understood that the meaning of “on”, “above”, and “over” in the present disclosure should be interpreted in the broadest manner such that “on” not only includes the meaning of “on” something with no intermediate feature or layer therebetween (i.e., directly on something) but also includes the meaning of “on” something with an intermediate feature or a layer therebetween.

In the embodiments of the present disclosure, the terms “first”, “second”, “third”, and the like are used for distinguishing similar objects and are not necessarily used for describing a particular order or sequence.

In the embodiments of the present disclosure, the term “layer” refers to a material portion that includes a region having a thickness. A layer may extend over the entirety of the underlying or overlying structure or may have an extent that is less than the extent of the underlying or overlying structure. Furthermore, a layer may be a region of a homogeneous or inhomogeneous continuous structure having a thickness less than the thickness of a continuous structure. For example, a layer may be located between the top surface and the bottom surface of a continuous structure, or a layer may be located between any pair of horizontal planes at the top surface and the bottom surface of the continuous structure. A layer may extend horizontally, perpendicularly, and/or along inclined surfaces. A layer may include a plurality of sub-layers.

It should be noted that the technical solutions described in the embodiments of the present disclosure may be combined arbitrarily without conflict.

FIG. 1 is a schematic plan view of an image sensor device;

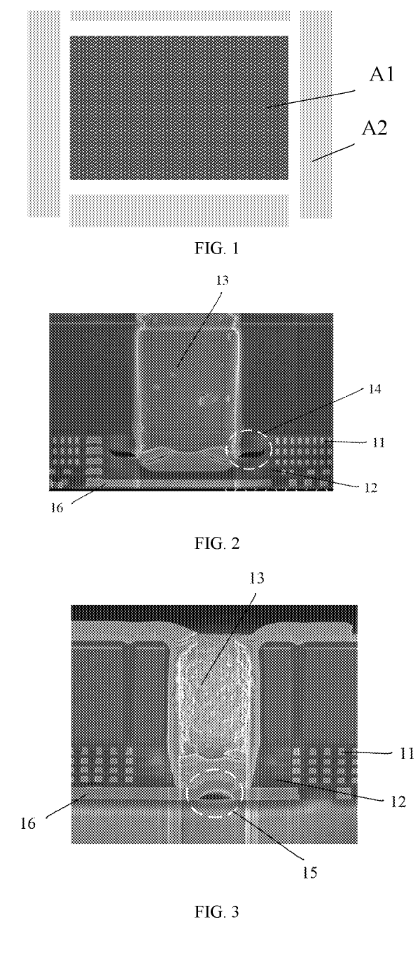

FIGS. 2 and 3 are schematic diagrams of a scanning electron microscope of an image sensor according to an embodiment;

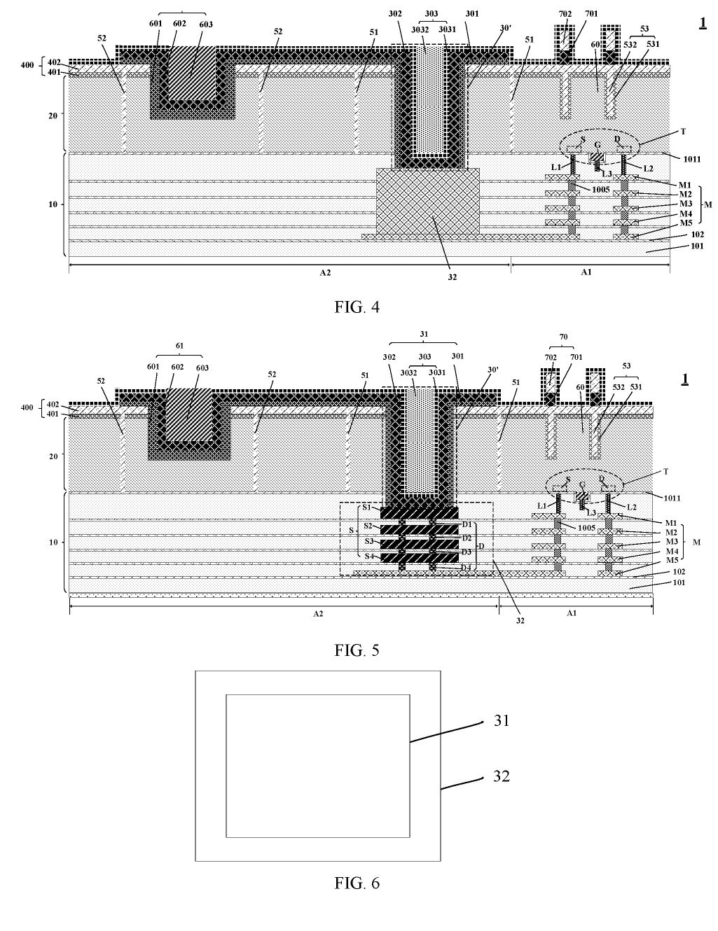

FIG. 4 is a schematic diagram of a semiconductor structure according to the present disclosure;

FIG. 5 is a schematic diagram of another semiconductor structure according to the present disclosure;

FIGS. 6 to 8 are schematic top views of a first structure and a second structure according to the present disclosure;

FIG. 9 is a schematic diagram of an image sensor according to the present disclosure;

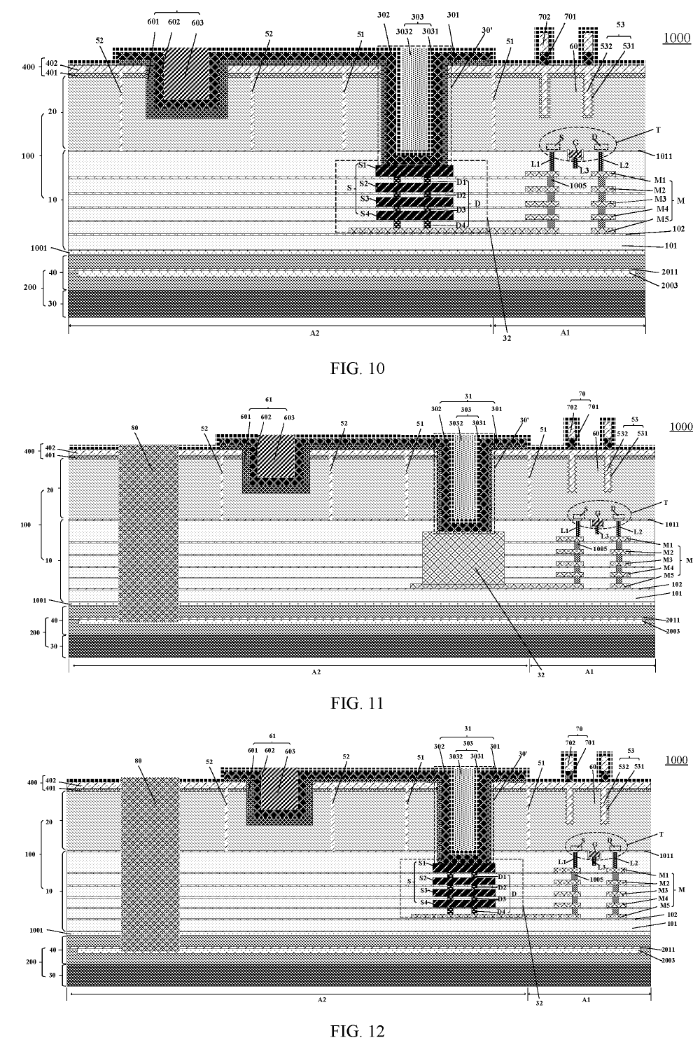

FIG. 10 is a schematic diagram of another image sensor according to the present disclosure;

FIG. 11 is a schematic diagram of an image sensor including a through structure according to the present disclosure; and

FIG. 12 is a schematic diagram of another image sensor including a through structure according to the present disclosure.

Referring to FIG. 1, the image sensor device includes a pixel region A1 and a peripheral region A2, and the peripheral region A2 is located on at least one side of the pixel region A1. FIG. 1 shows that the peripheral region A2 is located around the pixel region A1. Certainly, the peripheral region A2 may also be located on two or three sides of the pixel region A1, which may be specifically configured as needed. The pixel region A1, a core region of the image sensor, is mainly responsible for capturing light and converting an optical signal into an electrical signal. The pixel region A1 mainly includes a photodiode (photodiode), a transfer transistor (transfer transistor), a reset transistor (reset transistor), a source follower (source follower) or amplification transistor (amplification transistor), a row select transistor (row select transistor), and the like. The peripheral region surrounds the pixel region and is mainly responsible for signal processing, control, and interface functions. The peripheral region mainly includes readout circuitry (readout circuitry), control circuitry (control circuitry), row/column driver circuits (row/column driver circuits), timing and logic circuits (timing and logic circuits), interface circuits (interface circuits), memory circuits (memory circuits), power management circuits (power management circuits), and the like. A back side via (Back Side Via, BSV) is usually provided in the peripheral region A2 for signal connection and transmission. FIGS. 2 and 3 are schematic diagrams of a scanning electron microscope of an image sensor according to an embodiment. As shown in FIG. 2, the image sensor includes a plurality of metal layers 11, a bottommost metal layer 16, a BSV 13, and a dielectric layer 12. The dielectric layer 12 is filled between adjacent metal layers as well as between the plurality of metal layers and the BSV. However, a crack 14 may exist in the dielectric layer 12 of the image sensor. As indicated by the white dashed lines in FIG. 2, the presence of the crack 14 affects the stability of the overall structure. In addition, in some cases, the BSV 13 and the bottommost metal layer 16 need to be electrically connected for analog-to-digital conversion. However, as shown in FIG. 2, there may also be a case where the BSV 13 cannot be electrically connected to the bottommost metal layer 16, resulting in an open circuit and affecting the connection performance between structures of the image sensor. As shown in FIG. 3, when the BSV 13 comes into contact with the bottommost metal layer 16, the bottommost metal layer 16 may be deformed due to the combination of a tensile stress of the BSV 13 and a compressive stress of the bottommost metal layer 16, leading to the formation of a hole 15. The presence of the hole 15 further reduces the connection performance and structural stability of the image sensor. In view of the above problems, the present application provides a semiconductor structure and an image sensor to improve the contact performance and structural stability of the image sensor.

As shown in FIG. 4, a semiconductor structure 1 includes: a base substrate 10 and an epitaxial layer 20, the epitaxial layer 20 being located on the base substrate 10, and the base substrate 10 including a pixel region A1 and a peripheral region A2; a first opening 30' as indicated by a dashed box in FIG. 4, the first opening 30' penetrating through the epitaxial layer 20 into the base substrate 10; a first structure 31 located in the first opening; and a second structure 32 located in the base substrate 10. The second structure 32 is located below the first structure 31, and the second structure 32 is electrically connected to the first structure 31. The first structure 31 includes a first dielectric layer 301, a conductive layer 302, and a filling layer 303. The first dielectric layer 301 covers a side wall of the first opening 30', the conductive layer 302 covers the first dielectric layer 301 and covers the bottom of the first opening 30', the conductive layer 302 is electrically connected to the second structure 32, and the filling layer 303 covers at least the conductive layer 302. In a specific embodiment, the filling layer 303 includes a first filling layer 3031 and a second filling layer 3032. The material of the first dielectric layer 301 may be silicon nitride, silicon oxide, or silicon oxynitride, the material of the conductive layer 302 may be tungsten, and the material of the filling layer 303 may be silicon nitride, silicon oxide, or silicon oxynitride, or may be a filter material such as a color filter (color filter). In a specific embodiment, the first filling layer 3031 may be one or more of silicon nitride, silicon oxide, or silicon oxynitride, and the second filling layer 3032 may be a filter material such as a color filter (color filter).

The base substrate 10 includes a dielectric layer 101 and a barrier layer 102 that are stacked. The base substrate 10 further includes a metal layer M. The metal layer M is located in the dielectric layer 101, and the metal layer M includes at least a first metal layer M1, a second metal layer M2, a third metal layer M3, a fourth metal layer M4, and a fifth metal layer M5 from top to bottom. The fifth metal layer M5 extends in a direction parallel to the base substrate 10 to a position below the first opening 30', the second structure 32 is located between the fifth metal layer M5 and the first structure 31, and the second structure 32 is electrically connected to the fifth metal layer M5 and the first structure 31. The material of the metal layer M may be copper or tungsten, and the barrier layer 102 is configured to prevent diffusion of the metal layer M. The projected area of the first structure 31 on the fifth metal layer M5 is not greater than the projected area of the second structure 32 on the fifth metal layer M5.

In a specific embodiment, as shown in FIG. 4, the second structure 32 is columnar, and the dielectric layer 101 and the barrier layer 102 are both connected to the side wall of the second structure 32. As shown in FIG. 2 above, a crack 14 may exist in the dielectric layer 12 of the image sensor, and the presence of the crack 14 may affect the stability of the overall structure. The main causes of the crack 14 are explained herein with reference to FIGS. 2 and 4: The semiconductor structure 1 includes a base substrate 10 and an epitaxial layer 20, the epitaxial layer 20 is mainly made of silicon (Si), the base substrate 10 includes a dielectric layer 101 and a barrier layer 102 that are stacked, and the main material of the dielectric layer 101 is a low-K dielectric layer. Due to the large coefficient of thermal expansion of Si and the small coefficient of thermal expansion of the low-K dielectric layer, a weak point (weak point) exists between the dielectric layer 101 and the barrier layer 102, especially after the BSV hole is formed. Some thermal processes are involved in the subsequent process. During these thermal processes, the difference in the coefficient of thermal expansion causes the weak point to further expand, resulting in a crack. In the embodiments of the present application, the second structure 32 is provided, in advance, in a region that is originally prone to cracking, and the presence of the second structure 32 can prevent the weak point from being exposed, thereby preventing the expansion of the weak point and the formation of cracks. In addition, the second structure 32 and the metal layer M in the dielectric layer 101 may be made of the same material, thereby preventing the influence caused by the difference in the coefficient of thermal expansion.

Furthermore, as shown in FIG. 3, when the BSV 13 comes into contact with the bottommost metal layer 16, the bottommost metal layer 16 may be deformed due to the combination of a tensile stress of the BSV 13 and a compressive stress of the bottommost metal layer 16, leading to the formation of a hole 15. The presence of the hole 15 further reduces the connection performance and structural stability of the image sensor. In the embodiments of the present application, the second structure 32 is directly disposed above the fifth metal layer M5, and the second structure 32 may be in a block shape. The second structure 32 may generate a relatively large compressive stress to prevent the formation of a hole in the fifth metal layer M5 due to warping and deformation, thereby further improving the stability of the semiconductor structure. In addition, the second structure 32 is located below the first structure 31, such that the first structure 31 can be electrically connected to the fifth metal layer M5 through the second structure 32, thereby preventing the occurrence of an open circuit. The upper surface of the second structure 32 is not lower than the upper surface of the first metal layer M1, such that the first structure 31 is better electrically connected to the second structure 32, thereby preventing the risk of connection failure between the first structure 31 and the second structure 32.

A transistor T is further provided in the base substrate 10. The transistor T is provided with a source S, a drain D, and a gate G. The source S and the drain D are electrically connected to the first metal layer M1 through a first electrical connecting structure L1 and a second electrical connecting structure L2, respectively. In a specific embodiment, the gate G is further connected to a third electrical connecting structure L3. It should be noted that the metal layers at the same layer may not all be connected due to reasons such as wiring density, signal isolation, and thermal management. As shown in FIG. 4, both the source S and the drain D are electrically connected to the first metal layer M1. However, since the first metal layer M1 is discontinuous, the source and the drain can separately transmit signals through the first metal layer M1. An isolation layer 400 is further provided on the epitaxial layer 20, and the isolation layer 400 includes a first isolation layer 401 and a second isolation layer 402. The first isolation layer 401 may be a high-K dielectric layer, the second isolation layer 402 may be an oxide layer, and the isolation layer 400 can reduce the dark current of the image sensor. A first barrier layer 1011 is further provided between the epitaxial layer 20 and the base substrate 10, a first isolation structure 51 is further provided on both sides of the first structure 31, and the first isolation structure 51 extends from the isolation layer 400 to the first barrier layer 1011. The epitaxial layer 20 is further provided with a contact pad 61, and the contact pad 61 includes a pad dielectric layer 601, a pad metal layer 602, and a pad 603. The material of the pad dielectric layer 601 may be the same as the material of the first dielectric layer 301, and the material of the pad metal layer 602 may be the same as the material of the conductive layer 302. The contact pad 61 extends into the epitaxial layer 20, and the exposed surface at the top of the contact pad 61 may be electrically connected to other wires. By applying a voltage to the contact pad 61, the contact pad 61 is electrically connected to the first structure, the first structure 31 is electrically connected to the second structure 32, and the second structure 32 is electrically connected to the transistor T through the fifth metal layer M5; that is, the applied voltage is transferred from the contact pad 61 to the transistor T, and then the transistor T performs a corresponding reading operation based on the applied voltage. A second isolation structure 52 is further provided on both sides of the contact pad 61, and the second isolation structure 52 extends from the isolation layer 400 to the first barrier layer 1011. The epitaxial layer 20 is further provided with pixel regions 60, and the pixel regions 60 are isolated by a third isolation structure 53. The third isolation structure 53 includes a first sub-isolation structure 531 and a second sub-isolation structure 532. The first sub-isolation structure 531 may be one or both of tantalum oxide or a high-K dielectric layer, the second sub-isolation structure 532 may be silicon oxide, and the third isolation structure 53 reduces the dark current of the image sensor; the third isolation structure 53 extends from the isolation layer 400 into the epitaxial layer 20. A metal mesh structure 70 is further provided above the pixel regions 60, the metal mesh structure 70 includes a mesh structure conductive layer 701 and a cap layer 702, the first filling layer 3031 covers the top and the side wall of the metal mesh structure 70, and the metal mesh structure 70 is configured to prevent crosstalk between the pixel regions 60.

In the embodiments of the present application, by providing, in advance, the second structure 32 in a region that is originally prone to cracking, the presence of the second structure 32 can prevent the weak point from being exposed, thereby preventing the expansion of the weak point and the formation of cracks. In addition, the second structure 32 and the metal layer M in the dielectric layer 101 may be made of the same material, thereby preventing the influence caused by the difference in the coefficient of thermal expansion. In the embodiments of the present application, the second structure 32 is directly disposed above the fifth metal layer M5, and the second structure 32 may be in a block shape. The second structure 32 may generate a relatively large compressive stress to prevent the formation of a hole in the fifth metal layer M5 due to warping and deformation, thereby further improving the stability of the semiconductor structure. In addition, the second structure 32 is located below the first structure 31, such that the first structure 31 can be electrically connected to the fifth metal layer M5 through the second structure 32, thereby preventing the occurrence of an open circuit.

Next, referring to FIG. 5, FIG. 5 is a schematic diagram of another semiconductor structure according to the present disclosure. The identical parts will not be described again. The difference between the embodiments of the present application and the previous embodiment lies in that the second structure 32 is composed of a connecting layer S and a conducting structure D, as indicated by the dashed lines in FIG. 5; the connecting layer S is located in the dielectric layer 101, there may be one or more conducting structures D, and upper and lower adjacent connecting layers S are electrically connected through the conducting structure D; the connecting layer S includes at least a first connecting layer S1, a second connecting layer S2, a third connecting layer S3, and a fourth connecting layer S4 from top to bottom; the conducting structure D includes at least a first conducting structure D1, a second conducting structure D2, a third conducting structure D3, and a fourth conducting structure D4 from top to bottom; the first connecting layer S1 and the second connecting layer S2 are electrically connected through the first conducting structure D1, the second connecting layer S2 and the third connecting layer S3 are electrically connected through the second conducting structure D2, the third connecting layer S3 and the fourth connecting layer S4 are electrically connected through the third conducting structure D3, and the fourth connecting layer S4 and the fifth metal layer M5 are electrically connected through the fourth conducting structure D4. The connecting layer S and the metal layer M are located at the same level. It should be noted herein that the connecting layer S and the metal layer M being located at the same level means that the connecting layer S and the metal layer M at each level are located in the same dielectric layer 101. For example, the first connecting layer S1 and the first metal layer M1 are located in the same dielectric layer 101, the second connecting layer S2 and the second metal layer M2 are located in the same dielectric layer 101, the third connecting layer S3 and the third metal layer M3 are located in the same dielectric layer 101, and the fourth connecting layer S4 and the fourth metal layer M4 are located in the same dielectric layer 101. In a specific embodiment, the first connecting layer S1 and the first metal layer M1 may be formed by deposition in the same step, the second connecting layer S2 and the second metal layer M2 may be formed by deposition in the same step, the third connecting layer S3 and the third metal layer M3 may be formed by deposition in the same step, and the fourth connecting layer S4 and the fourth metal layer M4 may be formed by deposition in the same step. There may be one or more conducting structures D, which may be specifically configured as needed. In the embodiments of the present application, two conducting structures D are illustratively shown, and the first structure 31 is electrically connected to the fifth metal layer M5 by means of the multi-layer arrangement of the connecting layer S and the conducting structure D.

In the embodiments of the present application, the second structure 32 is configured as the connecting layer S and the conducting structure D. The connecting layer S and the metal layer M may be formed in the same deposition process; that is, there is no weak point (weak point) between the dielectric layer 101 and the barrier layer 102 after the BSV hole is formed. Since the second structure 32 according to the embodiments of the present application is deposited layer by layer, without hole forming process, no weak point is generated. Even if a thermal process is involved in the subsequent process, the weak point will not further expand and develop into a crack. In the embodiments of the present application, the arrangement of the second structure can prevent the generation and expansion of weak points as well as the formation of cracks. In addition, the fourth connecting layer S4 of the second structure is electrically connected to the fifth metal layer M5 through a fourth conductive structure D4, and the small tensile stress of the fourth conductive structure D4 does not cause the fifth metal layer M5 to be warped and deformed to form a hole, thereby further improving the stability of the semiconductor structure. In addition, the second structure 32 is located below the first structure 31, such that the first structure 31 can be electrically connected to the fifth metal layer M5 through the second structure 32, thereby preventing the occurrence of an open circuit.

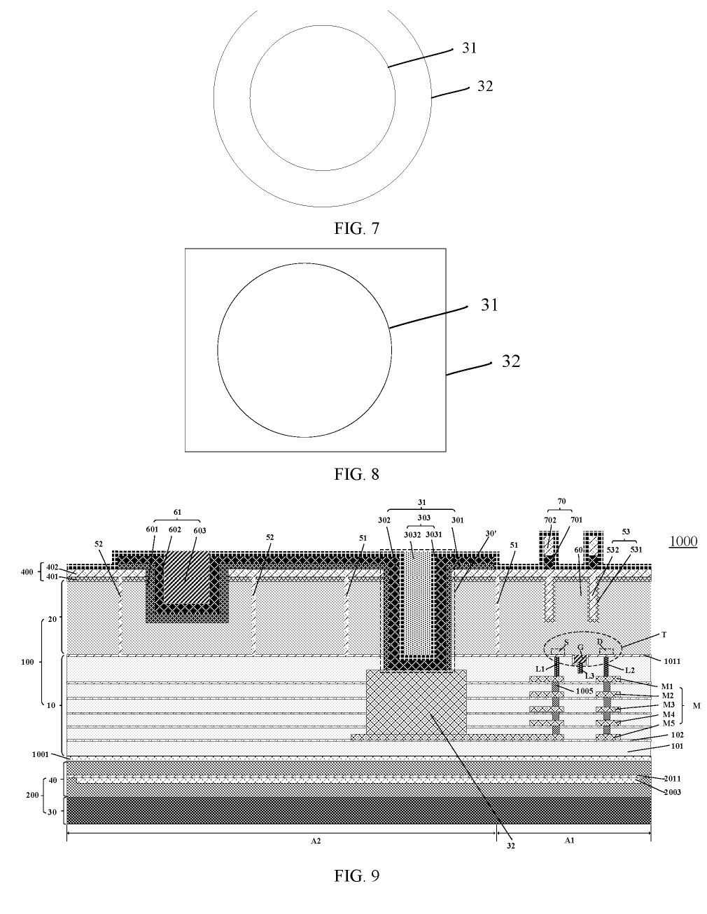

FIGS. 6 to 8 are schematic top views of a first structure and a second structure according to the present disclosure. In the embodiments of the present application, the top view of the first structure 31 may be a polygon or a circle. Specifically, the polygon may be a square, a rectangle, or the like. The top view of the second structure 32 may be a quadrangle or a circle. In a specific embodiment, as shown in FIG. 6, both the first structure 31 and the second structure 32 are quadrangles; as shown in FIG. 7, both the first structure 31 and the second structure 32 are circles; and as shown in FIG. 8, the first structure 31 is a quadrangle, and the second structure 32 is a circle. It should be noted that, regardless of the shapes of the first structure 31 and the second structure 32, the top view area of the second structure 32 is greater than the top view area of the first structure 31; that is, the projected area of the first structure 31 on the fifth metal layer M5 is not greater than the projected area of the second structure 32 on the fifth metal layer M5. This arrangement offers the advantage of allowing the first structure 31 to more easily land on the second structure 32; that is, the second structure 32 provides more space for the landing of the first structure 31, thereby preventing the problems that would arise from incomplete contact between the first structure 31 and the second structure 32.

FIG. 9 is a schematic diagram of an image sensor according to the present disclosure. As shown in FIG. 9, an image sensor 1000 includes: a first semiconductor 100 and a second semiconductor 200. The first semiconductor 100 is located on the second semiconductor 200, and the first semiconductor 100 includes a base substrate 10 and an epitaxial layer 20 located on the base substrate 10; the second semiconductor 200 includes a substrate 30 and a structural layer 40 located on the substrate, a bonding layer 1001 is provided between the top surface of the structural layer 40 and the bottom surface of the base substrate 10, and the bonding manner of the bonding layer 1001 may be direct bonding or wafer bonding. The structural layer 40 includes a structural conductive layer 2003, and a second barrier layer 2011 is further provided on the structural conductive layer 2003. During the fabrication process, both the first barrier layer 1011 and the second barrier layer 2011 are used as etch barrier layers to prevent over-etching from affecting other structures.

With reference to FIGS. 4 and 9, the first semiconductor 100 includes: a base substrate 10 and an epitaxial layer 20, the epitaxial layer 20 being located on the base substrate 10; a first opening 30' as indicated by the dashed box in FIG. 9, the first opening 30' penetrating through the epitaxial layer 20 into the base substrate 10; a first structure 31 located in the first opening; and a second structure 32 located in the base substrate 10. The second structure 32 is located below the first structure 31, and the second structure 32 is electrically connected to the first structure 31. The first structure 31 includes a first dielectric layer 301, a conductive layer 302, and a filling layer 303. The first dielectric layer 301 covers a side wall of the first opening 30', the conductive layer 302 covers the first dielectric layer 301 and covers the bottom of the first opening 30', the conductive layer 302 is electrically connected to the second structure 32, and the filling layer 303 covers at least the conductive layer 302. In a specific embodiment, the filling layer 303 includes a first filling layer 3031 and a second filling layer 3032. The material of the first dielectric layer 301 may be silicon nitride, silicon oxide, or silicon oxynitride, the material of the conductive layer 302 may be tungsten, and the material of the filling layer 303 may be silicon nitride, silicon oxide, or silicon oxynitride, or may be a filter material such as a color filter (color filter). In a specific embodiment, the first filling layer 3031 may be one or more of silicon nitride, silicon oxide, or silicon oxynitride, and the second filling layer 3032 may be a filter material such as a color filter (color filter). The base substrate 10 includes a dielectric layer 101 and a barrier layer 102 that are stacked. The base substrate 10 further includes a metal layer M. The metal layer M is located in the dielectric layer 101, and the metal layer M includes at least a first metal layer M1, a second metal layer M2, a third metal layer M3, a fourth metal layer M4, and a fifth metal layer M5 from top to bottom. The fifth metal layer M5 extends in a direction parallel to the base substrate 10 to a position below the first opening 30', the second structure 32 is located between the fifth metal layer M5 and the first structure 31, and the second structure 32 is electrically connected to the fifth metal layer M5 and the first structure 31. The material of the metal layer M may be copper or tungsten, and the barrier layer 102 is configured to prevent diffusion of the metal layer M. The projected area of the first structure 31 on the fifth metal layer M5 is not greater than the projected area of the second structure 32 on the fifth metal layer M5.

In a specific embodiment, as shown in FIG. 9, the second structure 32 is columnar, and the dielectric layer 101 and the barrier layer 102 are both connected to the side wall of the second structure 32. As shown in FIG. 2 above, a crack 14 may exist in the dielectric layer 12 of the image sensor, and the presence of the crack 14 may affect the stability of the overall structure. The main causes of the crack 14 are explained herein with reference to FIGS. 2 and 9: The semiconductor structure 1 includes a base substrate 10 and an epitaxial layer 20, the epitaxial layer 20 is mainly made of silicon (Si), the base substrate 10 includes a dielectric layer 101 and a barrier layer 102 that are stacked, and the dielectric layer 101 is mainly a low-K dielectric layer. Due to the large coefficient of thermal expansion of Si and the small coefficient of thermal expansion of the low-K dielectric layer, a weak point (weak point) exists between the dielectric layer 101 and the barrier layer 102, especially after the BSV hole is formed. Some thermal processes are involved in the subsequent process. During these thermal processes, the difference in the coefficient of thermal expansion causes the weak point to further expand, resulting in a crack. In the embodiments of the present application, the second structure 32 is provided, in advance, in a region that is originally prone to cracking, and the presence of the second structure 32 can prevent the weak point from being exposed, thereby preventing the expansion of the weak point and the formation of cracks. In addition, the second structure 32 and the metal layer M in the dielectric layer 101 may be made of the same material, thereby preventing the influence caused by the difference in the coefficient of thermal expansion.

Furthermore, as shown in FIG. 3, when the BSV 13 comes into contact with the bottommost metal layer 16, the bottommost metal layer 16 may be deformed due to the combination of a tensile stress of the BSV 13 and a compressive stress of the bottommost metal layer 16, leading to the formation of a hole 15. The presence of the hole 15 further reduces the connection performance and structural stability of the image sensor. In the embodiments of the present application, the second structure 32 is directly disposed above the fifth metal layer M5, and the second structure 32 may be in a block shape. The second structure 32 may generate a relatively large compressive stress to prevent the formation of a hole in the fifth metal layer M5 due to warping and deformation, thereby further improving the stability of the semiconductor structure. In addition, the second structure 32 is located below the first structure 31, such that the first structure 31 can be electrically connected to the fifth metal layer M5 through the second structure 32, thereby preventing the occurrence of an open circuit. The upper surface of the second structure 32 is not lower than the upper surface of the first metal layer M1, such that the first structure 31 is better electrically connected to the second structure 32, thereby preventing the risk of connection failure between the first structure 31 and the second structure 32.

A transistor T is further provided in the base substrate 10. The transistor T is provided with a source S, a drain D, and a gate G. The source S and the drain D are electrically connected to the first metal layer M1 through a first electrical connecting structure L1 and a second electrical connecting structure L2, respectively. In a specific embodiment, the gate G is further connected to a third electrical connecting structure L3. An isolation layer 400 is further provided on the epitaxial layer 20, and the isolation layer 400 includes a first isolation layer 401 and a second isolation layer 402. The first isolation layer 401 may be a high-K dielectric layer, the second isolation layer 402 may be an oxide layer, and the isolation layer 400 can reduce the dark current of the image sensor. A first barrier layer 1011 is further provided between the epitaxial layer 20 and the first base substrate 10, a first isolation structure 51 is further provided on both sides of the first structure 31, and the first isolation structure 51 extends from the isolation layer 400 to the first barrier layer 1011. The epitaxial layer 20 is further provided with a contact pad 61, and the contact pad 61 includes a pad dielectric layer 601, a pad metal layer 602, and a pad 603. The material of the pad dielectric layer 601 is the same as the material of the first dielectric layer 301, and the material of the pad metal layer 602 may be the same as the material of the conductive layer 302. The contact pad 61 extends into the epitaxial layer 20, and the exposed surface at the top of the contact pad 61 may be electrically connected to other wires. By applying a voltage to the contact pad 61, the contact pad 61 is electrically connected to the first structure, the first structure 31 is electrically connected to the second structure 32, and the second structure 32 is electrically connected to the transistor T through the fifth metal layer M5; that is, the applied voltage is transferred from the contact pad 61 to the transistor T, and then the transistor T performs a corresponding reading operation based on the applied voltage. A second isolation structure 52 is further provided on both sides of the contact pad 61, and the second isolation structure 52 extends from the isolation layer 400 to the first barrier layer 1011. The epitaxial layer 20 is further provided with pixel regions 60, and the pixel regions 60 are isolated by a third isolation structure 53. The third isolation structure 53 includes a first sub-isolation structure 531 and a second sub-isolation structure 532. The first sub-isolation structure 531 may be one or both of tantalum oxide or a high-K dielectric layer, the second sub-isolation structure 532 may be silicon oxide, and the third isolation structure 53 reduces the dark current of the image sensor; the third isolation structure 53 extends from the isolation layer 400 into the epitaxial layer 20. A metal mesh structure 70 is further provided above the pixel regions 60, the metal mesh structure 70 includes a mesh structure conductive layer 701 and a cap layer 702, the first filling layer 3031 covers the top and the side wall of the metal mesh structure 70, and the metal mesh structure 70 is configured to prevent crosstalk between the pixel regions 60.

In the embodiments of the present application, by providing, in advance, the second structure 32 in a region of the image sensor that is originally prone to cracking, the presence of the second structure 32 can prevent the weak point from being exposed, thereby preventing the expansion of the weak point and the formation of cracks. In addition, the second structure 32 and the metal layer M in the dielectric layer 101 may be made of the same material, thereby preventing the influence caused by the difference in the coefficient of thermal expansion. In the embodiments of the present application, the second structure 32 is directly disposed above the fifth metal layer M5, and the second structure 32 may be in a block shape. The second structure 32 may generate a relatively large compressive stress to prevent the formation of a hole in the fifth metal layer M5 due to warping and deformation, thereby further improving the stability of the semiconductor structure. In addition, the second structure 32 is located below the first structure 31, such that the first structure 31 can be electrically connected to the fifth metal layer M5 through the second structure 32, thereby preventing the occurrence of an open circuit.

FIG. 10 is a schematic diagram of another image sensor according to the present disclosure. As shown in FIG. 10, an image sensor 1000 includes a first semiconductor 100 and a second semiconductor 200. The first semiconductor 100 is located on the second semiconductor 200, and the first semiconductor 100 includes a base substrate 10 and an epitaxial layer 20 located on the base substrate 10; the second semiconductor 200 includes a substrate 30 and a structural layer 40 located on the substrate, and a bonding layer 1001 is provided between the top surface of the structural layer 40 and the bottom surface of the base substrate 10. The structural layer 40 includes a structural conductive layer 2003, and a second barrier layer 2011 is further provided on the structural conductive layer 2003.

The identical parts will not be described again. The difference between the embodiments of the present application and the previous embodiment lies in that the first semiconductor 100 includes a second structure 32, and the second structure 32 is composed of a connecting layer S and a conducting structure D, as indicated by the dashed lines in FIG. 10; the connecting layer S is located in the dielectric layer 101, there may be one or more conducting structures D, and upper and lower adjacent connecting layers S are electrically connected through the conducting structure D; the connecting layer S includes at least a first connecting layer S1, a second connecting layer S2, a third connecting layer S3, and a fourth connecting layer S4 from top to bottom; the conducting structure D includes at least a first conducting structure D1, a second conducting structure D2, a third conducting structure D3, and a fourth conducting structure D4 from top to bottom; the first connecting layer S1 and the second connecting layer S2 are electrically connected through the first conducting structure D1, the second connecting layer S2 and the third connecting layer S3 are electrically connected through the second conducting structure D2, the third connecting layer S3 and the fourth connecting layer S4 are electrically connected through the third conducting structure D3, and the fourth connecting layer S4 and the fifth metal layer M5 are electrically connected through the fourth conducting structure D4. The connecting layer S and the metal layer M are located at the same level. It should be noted herein that the connecting layer S and the metal layer M being located at the same level means that the connecting layer S and the metal layer M at each level are located in the same dielectric layer 101. For example, the first connecting layer S1 and the first metal layer M1 are located in the same dielectric layer 101, the second connecting layer S2 and the second metal layer M2 are located in the same dielectric layer 101, the third connecting layer S3 and the third metal layer M3 are located in the same dielectric layer 101, and the fourth connecting layer S4 and the fourth metal layer M4 are located in the same dielectric layer 101. In a specific embodiment, the first connecting layer S1 and the first metal layer M1 may be formed by deposition in the same step, the second connecting layer S2 and the second metal layer M2 may be formed by deposition in the same step, the third connecting layer S3 and the third metal layer M3 may be formed by deposition in the same step, and the fourth connecting layer S4 and the fourth metal layer M4 may be formed by deposition in the same step. There may be one or more conducting structures D, which may be specifically configured as needed. In the embodiments of the present application, two conducting structures D are illustratively shown, and the first structure 31 is electrically connected to the fifth metal layer M5 by means of the multi-layer arrangement of the connecting layer S and the conducting structure D.

In the embodiments of the present application, the second structure 32 is configured as the connecting layer S and the conducting structure D. The connecting layer S and the metal layer M may be formed in the same deposition process; that is, there is no weak point (weak point) between the dielectric layer 101 and the barrier layer 102 after the BSV hole is formed. Since the second structure 32 according to the embodiments of the present application is deposited layer by layer, without hole forming process, no weak point is generated. Even if a thermal process is involved in the subsequent process, the weak point will not further expand and develop into a crack. In the embodiments of the present application, the arrangement of the second structure can prevent the generation and expansion of weak points as well as the formation of cracks. In addition, the fourth connecting layer S4 of the second structure is electrically connected to the fifth metal layer M5 through a fourth conductive structure D4, and the small tensile stress of the fourth conductive structure D4 does not cause the fifth metal layer M5 to be warped and deformed to form a hole, thereby further improving the stability of the semiconductor structure. In addition, the second structure 32 is located below the first structure 31, such that the first structure 31 can be electrically connected to the fifth metal layer M5 through the second structure 32, thereby preventing the occurrence of an open circuit.

FIG. 11 is a schematic diagram of an image sensor including a through structure according to the present disclosure. The embodiments of the present application differ from FIG. 9 in that the image sensor 1000 further includes a through structure 80, the through structure 80 is located in the peripheral region A2, the through structure 80 passes through the first semiconductor 100 into the second semiconductor 200 and is electrically connected to the structural conductive layer 2003, and the through structure 80 can transmit the signal of the first semiconductor 100 to the second semiconductor 200.

FIG. 12 is a schematic diagram of another image sensor including a through structure according to the present disclosure. The embodiments of the present application differ from FIG. 10 in that the image sensor 1000 further includes a through structure 80, the through structure 80 is located in the peripheral region A2, and the through structure 80 passes through the first semiconductor 100 into the second semiconductor 200 and is electrically connected to the structural conductive layer 2003.

Those of ordinary skill in the art can understand that the foregoing implementations are specific embodiments for practicing the present disclosure, while in practical application, various changes can be made to the implementations in form and detail without departing from the spirit and scope of the present disclosure. Any person skilled in the art can make various changes and modifications without departing from the spirit and scope of the present disclosure, and the protection scope of the present disclosure shall be defined by the appended claims.

What is claimed is:

1. A semiconductor structure, comprising:
a base substrate;
an epitaxial layer located on the base substrate;
a first opening penetrating through the epitaxial layer into the base substrate;
a first structure located in the first opening; and
a second structure located below the first structure, the second structure being electrically connected to the first structure.

2. The semiconductor structure according to claim 1, wherein the first structure comprises a first dielectric layer, a conductive layer, and a filling layer, the first dielectric layer covers a side wall of the first opening, the conductive layer covers the first dielectric layer and covers a bottom of the first opening, the conductive layer is electrically connected to the second structure, and the filling layer covers at least the conductive layer.

3. The semiconductor structure according to claim 1, wherein the base substrate comprises a dielectric layer and a barrier layer that are stacked, the base substrate further comprises a metal layer, the metal layer is located in the dielectric layer, and the metal layer comprises at least a first metal layer, a second metal layer, a third metal layer, a fourth metal layer, and a fifth metal layer from top to bottom; the fifth metal layer extends in a direction parallel to the base substrate to a position below the first opening, the second structure is located between the fifth metal layer and the first structure, and the second structure is electrically connected to the fifth metal layer and the first structure.

4. The semiconductor structure according to claim 3, wherein a projected area of the first structure on the fifth metal layer is not greater than a projected area of the second structure on the fifth metal layer.

5. The semiconductor structure according to claim 3, wherein the second structure is columnar, and the dielectric layer and the barrier layer are both connected to a side wall of the second structure.

6. The semiconductor structure according to claim 3, wherein the second structure is composed of a connecting layer and a conducting structure, the connecting layer is located in the dielectric layer, there may be one or more conducting structures, and upper and lower adjacent connecting layers are electrically connected through the conducting structure; the connecting layer comprises at least a first connecting layer, a second connecting layer, a third connecting layer, and a fourth connecting layer from top to bottom; the conducting structure comprises at least a first conducting structure, a second conducting structure, a third conducting structure, and a fourth conducting structure from top to bottom; the first connecting layer and the second connecting layer are electrically connected through the first conducting structure, the second connecting layer and the third connecting layer are electrically connected through the second conducting structure, the third connecting layer and the fourth connecting layer are electrically connected through the third conducting structure, and the fourth connecting layer and the fifth metal layer are electrically connected through the fourth conducting structure.

7. The semiconductor structure according to claim 6, wherein the connecting layer and the metal layer are located at a same level.

8. The semiconductor structure according to claim 3, wherein an upper surface of the second structure is not lower than an upper surface of the first metal layer.

9. The semiconductor structure according to claim 1, wherein a transistor is further provided in the base substrate, the transistor is provided with a source, a drain, and a gate, and the source and the drain are electrically connected to the first metal layer through a first electrical connecting structure and a second electrical connecting structure, respectively.

10. The semiconductor structure according to claim 1, wherein an isolation layer is further provided on the epitaxial layer, a first barrier layer is further provided between the epitaxial layer and the base substrate, a first isolation structure is further provided on both sides of the first structure, and the first isolation structure extends from the isolation layer to the first barrier layer.

11. The semiconductor structure according to claim 1, wherein the epitaxial layer is provided with a contact pad, the contact pad extends into the epitaxial layer, a second isolation structure is further provided on both sides of the contact pad, and the second isolation structure extends from the isolation layer to the first barrier layer.

12. The semiconductor structure according to claim 1, wherein the epitaxial layer is further provided with pixel regions, the pixel regions are isolated by a third isolation structure, and the third isolation structure extends from the isolation layer into the epitaxial layer.

13. The semiconductor structure according to claim 12, wherein a metal mesh structure is further provided above the pixel regions, and the metal mesh structure is configured to prevent crosstalk between the pixel regions.

14. An image sensor, comprising:
a first semiconductor and a second semiconductor, wherein the first semiconductor is located on the second semiconductor, and the first semiconductor is composed of the semiconductor structure according to claim 1;
the first semiconductor comprises a base substrate and an epitaxial layer located on the base substrate; and
the second semiconductor comprises a substrate and a structural layer located on the substrate, and a bonding layer is provided between a top surface of the structural layer and a bottom surface of the base substrate.

15. The image sensor according to claim 14, wherein the structural layer comprises a structural conductive layer, a second barrier layer is further provided on the structural conductive layer, and the image sensor further comprises a through structure, the through structure passing through the first semiconductor into the second semiconductor and being electrically connected to the structural conductive layer.
